(19) United States
(12) Patent Application Publication
(10) Pub. No.: US 2003/0020066 A1
(43) Pub. Date: Jan. 30, 2003

(54) Semiconductor device and manufacturing method thereof

(75) Inventors: Shigenori Kido, Hyogo (JP); Yukihiro Nagai, Hyogo (JP)

Correspondence Address: McDERMOTT, WILL & EMERY, 600 13th Street, N.W., Washington, DC, 20005-3096, US

(73) Assignee: Mitsubishi Denki Kabushiki Kaisha

(21) Appl. No.: 10/133,667

(22) Filed: Apr. 29, 2002

(30) Foreign Application Priority Data
Jul. 24, 2001 (JP) 2001-223227(P)

(51) Int. Cl. H01L 27/108; H01L 29/04; H01L 29/76; H01L 31/036; H01L 31/112

(52) U.S. Cl. 257/68

(57) ABSTRACT

Storage node plugs are formed on a semiconductor substrate. A silicon nitride film is formed on a silicon oxide film. By etching the silicon oxide film with the silicon nitride film as a mask, storage node openings each exposing a surface of a corresponding storage node plug are formed, followed by forming a capacitor including a storage node, a capacitor dielectric film and a cell plate in a corresponding opening. With such a procedure, there can be obtained a semiconductor device in which electric short-circuit between adjacent elements is prevented from occurring; and a manufacturing method of such a semiconductor device.

### BACKGROUND OF THE INVENTION

1. Field of the Invention

The present invention relates to a semiconductor device and a manufacturing method thereof, and particularly, to a semiconductor device in which electric short-circuit between adjacent capacitors is prevented from occurring and a manufacturing method of the semiconductor device.

2. Description of the Background Art

Description will be given of a dynamic random access memory (hereinafter referred to as “DRAM”) including capacitors for storing information as an example of a prior art semiconductor device. First of all, a plan structure of a memory cell region therein is taken up. FIG. 33 shows a plan layout of the lower structure under an interlayer insulating film 113 covering capacitors and others. As shown in FIG. 33, plural element formation regions S are formed by trench isolation oxide film 102 on a main surface of a semiconductor substrate.

In each element formation region S, source/drain regions 104a and 104b are formed. A gate electrode 103 (word line) is formed on the semiconductor substrate that extends in one direction on the semiconductor substrate between source/drain regions 104a and 104b. A memory cell transistor is constituted of the gate electrode 103 and a pair of the source/drain regions 104a and 104b.

A bit line 107 is formed that is electrically connected to one of source/drain regions 104a and 104b of a pair. Bit line 107 extends in a direction approximately perpendicular to a direction along which gate electrode 103 extends.

A storage node (not shown) is formed that is electrically connected to the other of source/drain regions 104a and 104b of a pair. The storage node is, as described later, provided in a storage node opening 111 formed in an insulating film. A cell plate is formed on the storage node with a capacitor dielectric film interposing therebetween and a capacitor is constituted of the storage node, the capacitor dielectric film and the cell plate (see FIGS. 34 and 35).

Then, description will be given of a cross sectional structure along a direction (a cutting plane line XXXIV-XXXIV in FIG. 33) along which gate electrode 103 extends. As shown in FIG. 34, a plug 106a is formed in an insulating film 105, covering trench isolation film 102, and electrically connected to source/drain region 104a. A bit line 107 is formed on insulating film 105.

An insulating film 109 is formed so as to cover bit line 107. A storage node plug 108 is formed in insulating film 109 and electrically connected to plug 106a. An insulating film 110 is further formed on insulating film 109. A storage node opening 111 is formed in insulating film 110, which opening exposes a surface of storage node plug 108.

A storage node 112a is formed on the sidewall and bottom surfaces of storage node opening 111. A cell plate 112c is formed on storage node 112a with a capacitor dielectric film 112b interposing therebetween. A capacitor 112 is constituted of storage node 112a, capacitor dielectric film 112b and cell plate 112c. An interlayer insulating film 113 is formed so as to cover capacitor 112. A prior art DRAM is constituted as described above.

In a recent development toward an advanced micromanufacturing technology for DRAM, a necessity has arisen for increasing an aspect ratio of storage node opening 111 in which storage node 112a is provided, for securing a capacitance of capacitor 112. In addition thereto, another necessity has occurred for narrowing a distance between adjacent storage node openings 111.

Storage node opening 111 is, as shown in FIG. 35, formed by etching insulating film 110 with a prescribed photoresist 115 formed on insulating film 110 as a mask.

Especially, in a case where there is formed two storage node openings, each having a relatively large aspect ratio, and a narrow spacing therebetween, a photoresist 115a between the adjacent storage node openings has gotten thin in the course of etching, thereby disabling insulating film 110 with a prescribed thickness to be left between adjacent storage node openings 111 after the etching.

For this reason, storage nodes 112a formed in respective adjacent storage node openings 111 thereafter have been electrically short-circuited therebetween, thereby disabling DRAM to perform a prescribed operation.

### SUMMARY OF THE INVENTION

The present invention has been made in order to solve the above problem, and it is an object of the present invention to provide a semiconductor device in which electric short-circuit between adjacent elements is prevented from occurring and it is another object of the present invention to provide a manufacturing method of such a semiconductor device.

A semiconductor device in an aspect of the present invention includes: a conductive region; a first insulating film; openings; a second insulating film; and prescribed elements. The conductive region is formed on a main surface of a semiconductor substrate. The first insulating film is formed on the semiconductor substrate and has a prescribed etching property. The openings are formed in the first insulating film to expose a surface of the conductive region. The second insulating film is formed on a surface of the first insulating film other than at least sidewall and bottom surfaces of the openings, and has an etching property different from that of the first insulating film. The prescribed elements include conductive layers formed in the respective openings.

According to this structure, as described later, the openings are formed in the first insulating film by etching the first insulating film with the second insulating film as a mask. Hence, no chance is encountered that a photoresist is thinned and thereby the first insulating film is etched off in a case where etching is applied to the first insulating film with the photoresist as a mask, as is in a prior art case of manufacturing of a semiconductor device. With such a procedure, the first insulating film can be left between the adjacent openings with certainty, thereby enabling prevention of electric short-circuit between prescribed elements formed in the respective openings subsequent to the etching. As a result, a desired operation can be ensured in the semiconductor device.

To be concrete, it is preferable that openings are arranged in a matrix with a prescribed spacing between adjacent openings in one direction and a prescribed spacing between adjacent openings in the other direction approximately perpendicular thereto in the first insulating film, and the second insulating film is formed on the surface of the first insulating film at least in regions thereof between adjacent openings each with a narrower spacing.

With such a structure, there can be surely left the first insulating film in a region between adjacent openings with a narrower spacing.

Furthermore, it is preferable that the second insulating film is formed on a surface of the first insulating film other than the openings.

With such a structure, there can be surely left the first insulating film in a region between adjacent openings.

Furthermore, it is preferable that the semiconductor device includes a transistor including a gate electrode and a pair of source/drain regions of a prescribed conductivity type formed on the main surface of a semiconductor substrate, wherein the conductive region includes one of source/drain regions of the pair and each of the prescribed elements includes a capacitor having a storage node, electrically connected to the one of the source/drain regions as the conductive layer, and formed on sidewall and bottom surfaces of a corresponding one of the openings, and a cell plate formed on the storage node with a dielectric film interposing therebetween.

With such a structure, there can be obtained a memory cell including a transistor and a capacitor for use in a semiconductor device.

Furthermore, regarding kinds of film used in the first and second insulating film, it is preferable that the first insulating film includes a silicon oxide film and the second insulating film includes a silicon nitride film since those films are applicable with relative ease.

A manufacturing method of a semiconductor device in another aspect of the present invention includes the following steps: a conductive region is formed on a main surface of a semiconductor substrate. An insulating film having a prescribed etching property is formed on the semiconductor substrate. A mask material is formed on the insulating film. Openings exposing a surface of the conductive region are formed by etching the insulating film with the mask material as a mask. Prescribed elements are formed that each includes a conductive layer on side and bottom surfaces of a corresponding one of the openings. A step of forming a mask material includes a step of forming a prescribed layer not only different in an etching property from the insulating film but also different from a photoresist.

According to the manufacturing method of the semiconductor device, in a case where openings are formed in the insulating film by etching the insulating film with the mask material as a mask, no chance arises that a photoresist get thin and the insulating film is etched off, which would occur in case of manufacturing of a prior art semiconductor device where the insulating film is etched with the photoresist as a mask since the mask material not only is different in etching characteristic from the insulating film, but also includes a prescribed layer different from the photoresist film. With such a process adopted, the insulating film can be left between adjacent openings with certainty and thereby it is prevented from occurring that the prescribed elements thereafter formed in the openings are electrically short-circuited through a conductivity layer, enabling a semiconductor device performing a desired operation to be obtained with certainty.

To be concrete, it is preferable that in the step of forming a mask material, in order to form the openings arranged in a matrix with a prescribed spacing between adjacent openings in one direction and a prescribed spacing between adjacent openings in the other direction approximately perpendicular thereto in the insulating film, a prescribed layer is formed on a surface of the insulating film other than portions thereof in regions where the openings are formed; and in a step of forming the openings, the insulating film is etched with the prescribed layer as a mask to thereby form the openings arranged in a matrix.

With such a procedure adopted, the insulating film can be left in regions between adjacent openings with certainty.

Furthermore, it is preferable that in the step of forming a mask material, in order to form the openings arranged in a matrix with a prescribed spacing between adjacent openings in one direction and a prescribed spacing between adjacent openings in the other direction approximately perpendicular thereto in the insulating film, the prescribed layer is formed on a surface of the insulating film in regions each having a prescribed narrower spacing between adjacent openings while a photoresist is formed on the surface of the insulating film in regions each having a prescribed longer spacing between adjacent opening sections; and in the step of forming openings, the insulating film is etched with the prescribed layer and the photoresist as masks to thereby form the openings arranged in a matrix.

With such a manufacturing method adopted, the insulating film can be left in regions each having a narrower spacing between adjacent openings with more certainty.

Furthermore, it is preferable that the step of forming a mask material includes combined steps of forming depressions each having a prescribed depth and pattern feature on a surface of the insulating film and of forming the prescribed layer only in the depressions; or a step of forming the prescribed layer having prescribed pattern features each of a prescribed depth on a surface of the insulating film.

With such a procedure adopted, the mask material can be formed with certainty.

It is preferable that the manufacturing method includes: a step of forming a transistor including a gate electrode and a pair of source/drain regions of a prescribed conductivity type on the main surface of a semiconductor substrate prior to the step of forming an insulating film, wherein the step of forming a conductive region includes a step of forming the pair of source/drain regions and the step of forming prescribed elements includes a step of forming a storage node on sidewall and bottom surfaces of a corresponding one of said openings as a conductive layer, followed by formation of a cell plate on the storage node with a dielectric film interposing therebetween to form a capacitor.

Thereby, a semiconductor device is manufactured that has a memory cell including a transistor and capacitor.

Furthermore, regarding kinds of film used in the first and second insulating film, it is preferable that in the step of forming an insulating film, a silicon oxide film as the insulating film is formed and in the step of forming a mask material, a silicon nitride film as the prescribed layer is formed.

Alternatively, it is also preferable that a silicon oxide film as the insulating film is formed in the step of forming an insulating film while a polysilicon film as the prescribed layer is formed in the step of the mask material. Especially in this case, since the polysilicon film is conductive, it is required to remove the polysilicon film prior to formation of the prescribed elements after the openings are formed, in order to prevent electrical short-circuit from occurring.

The foregoing and other objects, features, aspects, and advantages of the present invention will become more apparent from the following detailed description of the present invention when taken in conjunction with the accompanying drawings.

### BRIEF DESCRIPTION OF THE DRAWINGS

FIG. 1 is a plan view of DRAM relating to a first embodiment of the present invention;

FIG. 2 is a cross sectional view taken on cutting plane line II-II shown in FIG. 1 in the first embodiment;

FIG. 3 is a cross sectional view taken on cutting plane line III-III shown in FIG. 1 in the first embodiment;

FIG. 4 is a cross sectional view corresponding to the cutting plane line II-II in FIG. 1, showing a step of a manufacturing method of DRAM relating to a second embodiment of the present invention;

FIG. 5 is a cross sectional view corresponding to the cutting plane line III-III in FIG. 1, showing a step of the manufacturing method of DRAM relating to a second embodiment of the present invention;

FIG. 6 is a cross sectional view showing a step performed subsequent to the step shown in FIG. 4 in the second embodiment;

FIG. 7 is a cross sectional view showing a step performed subsequent to the step shown in FIG. 5 in the second embodiment;

FIG. 8 is a cross sectional view showing a step performed subsequent to the step shown in FIG. 6 in the second embodiment;

FIG. 9 is a cross sectional view showing a step performed subsequent to the step shown in FIG. 1 in the second embodiment;

FIG. 10 is a plan view showing a step performed subsequent to the step shown in FIGS. 6 and 7 in the second embodiment;

FIG. 11 is a cross sectional view taken on cutting plane line XI-XI shown in FIG. 10 in the second embodiment;

FIG. 12 is a cross sectional view taken on cutting plane line XII-XII shown in FIG. 10 in the second embodiment;

FIG. 13 is a cross sectional view showing a step performed subsequent to the step shown in FIG. 11 in the second embodiment;

FIG. 14 is a cross sectional view showing a step performed subsequent to the step shown in FIG. 12 in the second embodiment;

FIG. 15 is a cross sectional view showing a step performed subsequent to the step shown in FIG. 13 in the second embodiment;

FIG. 16 is a cross sectional view showing a step performed subsequent to the step shown in FIG. 14 in the second embodiment;

FIG. 17 is a cross sectional view showing a step performed subsequent to the step shown in FIG. 15 in the second embodiment;

FIG. 18 is a cross sectional view showing a step performed subsequent to the step shown in FIG. 16 in the second embodiment;

FIG. 19 is a cross sectional view showing a step performed subsequent to the step shown in FIG. 17 in the second embodiment;

FIG. 20 is a cross sectional view showing a step performed subsequent to the step shown in FIG. 18 in the second embodiment;

FIG. 21 is a cross sectional view corresponding to the cutting plane line II-II in FIG. 1, showing a step of a manufacturing method of a semiconductor device relating to an example modification in the second embodiment;

FIG. 22 is a cross sectional view corresponding to the cutting plane line III-III in FIG. 1, showing a step of a manufacturing method of a semiconductor device relating to the example modification in the second embodiment;

FIG. 23 is a cross sectional view corresponding to the cutting plane line II-II in FIG. 1, showing a step of a manufacturing method of a semiconductor device relating another example modification in the second embodiment;

FIG. 24 is a cross sectional view corresponding to the cutting plane line XXIV-XXIV in FIG. 26, showing a step of a manufacturing method of DRAM relating to a third embodiment of the present invention;

FIG. 25 is a cross sectional view corresponding to the cutting plane line XXV-XXV in FIG. 26, showing a step of the manufacturing method of DRAM relating to a third embodiment of the present invention;

FIG. 26 is a plan view in the step shown in FIGS. 24 and 25 in the third embodiment;

FIG. 27 is a cross sectional view corresponding to the cutting plane line XXIV-XXIV in FIG. 26, showing a step performed subsequent to the step shown in FIG. 24 in the third embodiment;

FIG. 28 is a cross sectional view corresponding to the cutting plane line XXV-XXV in FIG. 26, showing a step performed subsequent to the step shown in FIG. 25 in the third embodiment;

FIG. 29 is a cross sectional view showing a step performed subsequent to the step shown in FIG. 27 in the third embodiment;

FIG. 30 is a cross sectional view showing a step performed subsequent to the step shown in FIG. 28 in the third embodiment;

FIG. 31 is a cross sectional view showing a step performed subsequent to the step shown in FIG. 29 in the third embodiment;

FIG. 32 is a cross sectional view showing a step performed subsequent to the step shown in FIG. 30 in the third embodiment;

FIG. 33 is a plan view of a prior art DRAM;

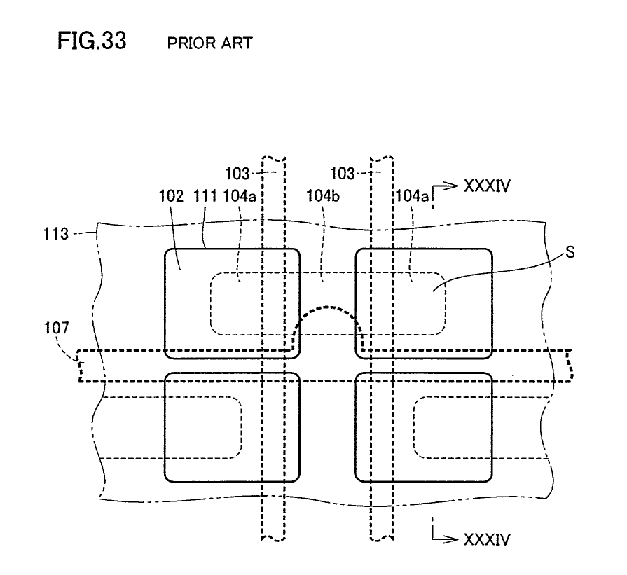

FIG. 34 is a cross sectional view taken on cutting plane line XXXIV-XXXIV shown in FIG. 33; and

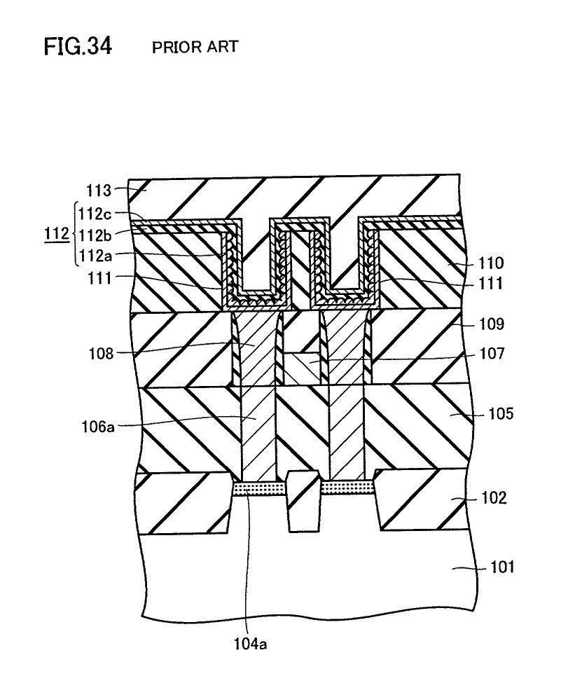

FIG. 35 is a cross sectional view for describing a problem associated with a prior art DRAM.

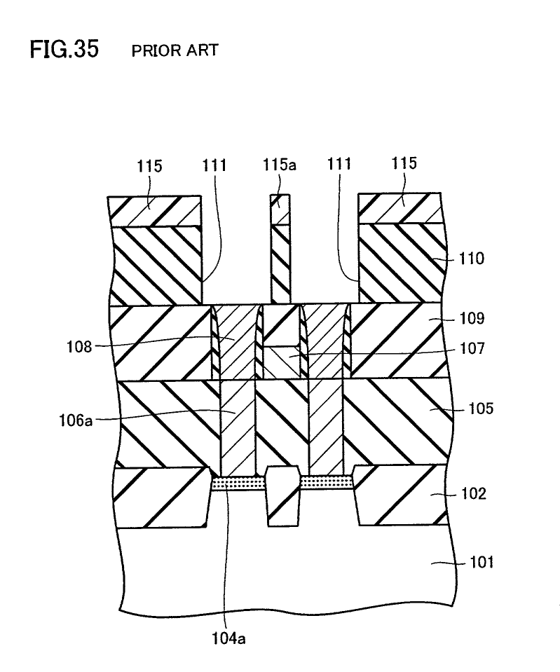

### DESCRIPTION OF THE PREFERRED EMBODIMENTS

### First Embodiment

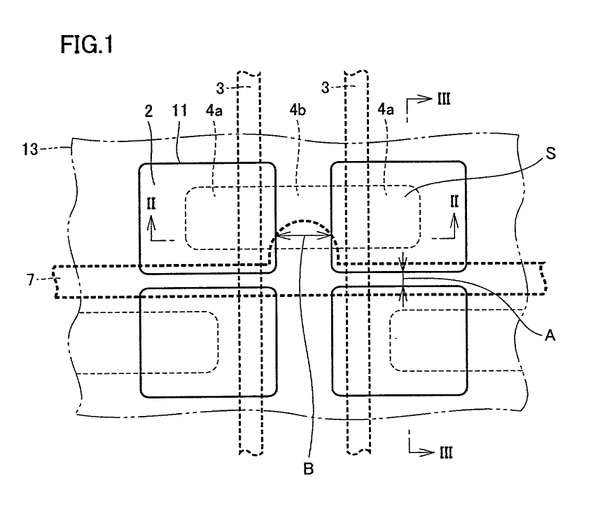

Description will be given of DRAM relating to the first embodiment of the present invention. First of all, a plan structure of a memory cell region thereof is taken up. FIG. 1 shows a plan layout of the lower structure under an interlayer insulating film 13 covering a capacitor and others. As shown in FIG. 1, plural element formation regions S are formed by trench isolation oxide film 2 on a main surface of a semiconductor substrate.

In each element formation region S, source/drain regions 4a and 4b are formed. A gate electrode 3 (word line) is formed that extends in one direction on the semiconductor substrate between the source/drain regions 4a and 4b. A memory cell transistor is constituted of gate electrode 3 and a pair of source/drain regions 4a and 4b.

A bit line 7 is formed that is electrically connected to one of source/drain regions 4a and 4b of a pair. Bit line 7 extends in a direction approximately perpendicular to a direction along which gate electrode 3 extends.

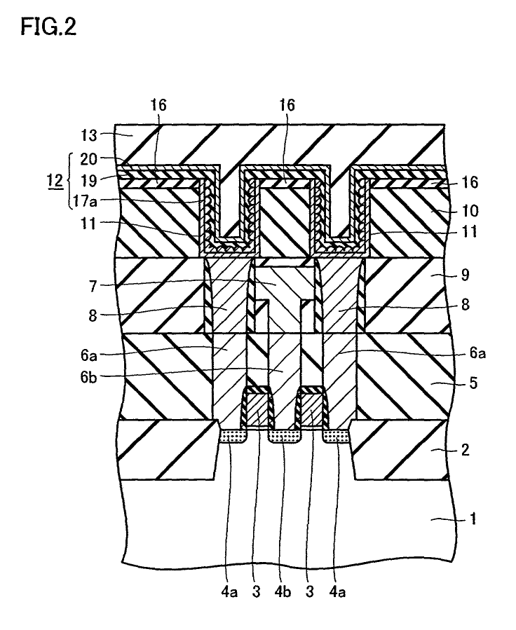

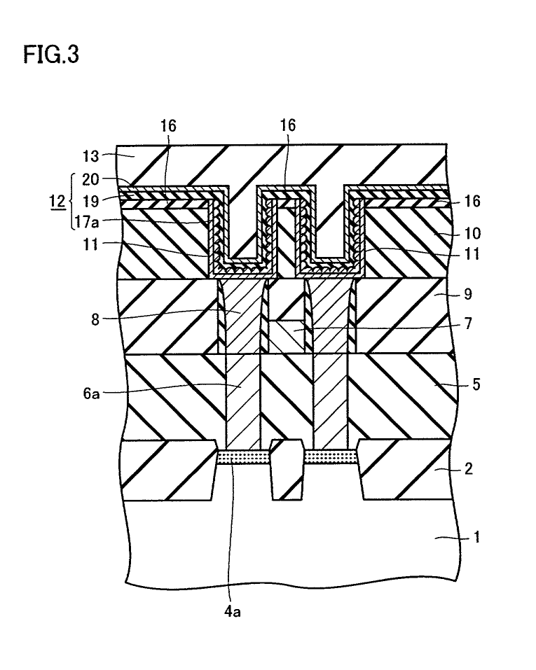

A storage node (not shown) is formed that is electrically connected to the other of the source/drain regions 4a and 4b of a pair. The storage node is, as described later, provided in a storage node opening 11 formed in an insulating film. A cell plate is formed on the storage node with a capacitor dielectric film interposing therebetween and a capacitor is constituted of the storage node, the capacitor dielectric film and the cell plate (see FIGS. 2 and 3).

Then, description will be given of a cross sectional structure along a direction (a cutting plane line II-II in FIG. 1) along which bit line 7 extends. As shown in FIG. 2, a pair of source/drain regions 4a and 4b is formed on an element formation region S sandwiched by trench isolation oxide film 2. Gate electrode 3 is formed on a region sandwiched by source/drain regions 4a and 4b of a pair on semiconductor substrate 1. An insulating film 5 is formed so as to cover gate electrode 3 on semiconductor substrate 1.

Plugs 6a and 6b are formed in insulating film 5 and are electrically connected to respective source/drain regions 4a and 4b. Bit line 7 is formed on insulating film 5 and electrically connected to plug 6.

An insulating film 9 is formed so as to cover bit line 7. A storage node plug 8 is formed in insulating film 9 and electrically connected to plug 6a. A silicon oxide film 10 as an insulating film is further formed on insulating film 9. A silicon nitride film 16 having a prescribed pattern is formed on silicon oxide film 10. By etching silicon oxide film 10 with silicon nitride film 16 as a mask, a storage node opening 11 is formed in silicon oxide film 10 and exposes a surface of storage node plug 8.

A storage node 17a is formed on the sidewall and bottom surfaces of storage node opening 11. A cell plate 20 is formed on storage node 17a with a capacitor dielectric film 19 interposing therebetween. A capacitor 12 is constituted of storage node 17a, capacitor dielectric film 19 and cell plate 20. An interlayer insulating film 13 is formed so as to cover capacitor 112.

Then, description will be given of a cross sectional structure along a direction (a cutting plane line III-III in FIG. 1) along which gate electrode extends. As shown in FIG. 3, plug 6a is formed in insulating film 5 and electrically connected to source/drain region 4a and bit line 7 is formed on insulating film 5. Storage node plug 8 is formed in insulating film 9 covering bit line 7 and electrically connected to plug 6a.

Silicon oxide film 10 is further formed on insulating film 9. Silicon nitride film 16 is formed on silicon oxide film 10. Etching is applied to silicon oxide film 10 with silicon nitride film 16 as a mask, thereby forming storage node opening 11.

Storage node 17a is formed in storage node opening 11. Cell plate 20 is formed on storage node 17a with capacitor dielectric film 19 interposing therebetween. Interlayer 13 is formed so as to cover capacitor 12. DRAM relating to the present invention is manufactured as described above.

In above DRAM, as described later, storage node opening 11 is formed in silicon oxide film 10 by performing anisotropic etching on silicon oxide film 16 with silicon nitride film 16 having an etching property different from that of silicon oxide film 10 as a mask.

Therefore, as compared with a case where anisotropic etching is applied to silicon oxide film 10 with a photoresist as a mask as performed in a prior art practice, thinning of silicon nitride film 16 as a mask is suppressed, thereby enabling silicon oxide film 10 to be left with certainty especially in a region of a narrower spacing between adjacent storage node openings shown in FIG. 3.

As a result, it can be prevented that storage nodes 17a formed subsequent to formation of storage node openings 11 are electrically short-circuited therebetween, thereby enabling a stable operation of DRAM to be secured.

Note that while, in this embodiment, silicon oxide film 10 is exemplified as an insulating film in which storage node openings 11 are formed and silicon nitride film 16 having an etching property different from that of a silicon oxide film is exemplified as a mask material for use in formation of storage node openings 11 in silicon oxide 10, no specific limitation is directed to such a combination of a silicon oxide film and a silicon nitride film as far as an insulating film can be substantially etched without etching off a mask material in formation of a storage node.

### Second Embodiment

Description will be given of an example of a manufacturing method of the above DRAM as the second embodiment of the present invention, taking up cross sectional views corresponding to cutting plane lines II-II and III-III shown in FIG. 1 and covering steps of the manufacturing.

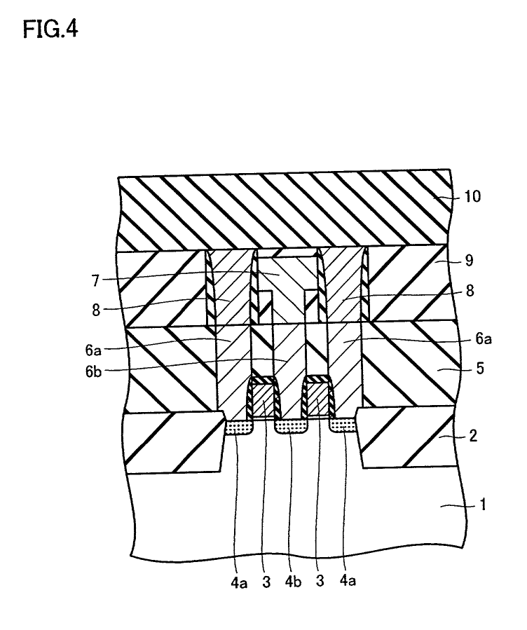

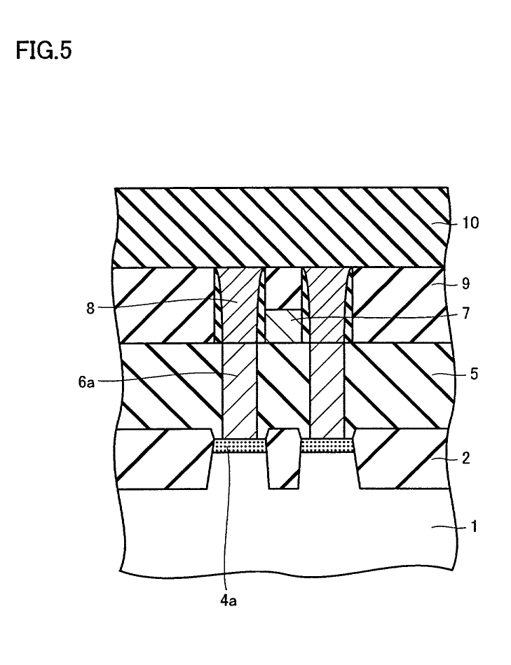

First of all, as shown in FIGS. 4 and 5, a trench isolation film 2 is formed on the main surface of semiconductor substrate 1. Gate electrode 3 is formed so as to traverse an element formation region formed by trench isolation film 2. A pair of source/drain regions 4a and 4b is formed in the element formation region by introducing impurity ions of a prescribed conductivity type into it with gate electrode 3 or the like as a mask. Insulating film 5 is formed so as to cover gate electrode 3 on semiconductor substrate 1 by means of, for example, a CVD (Chemical Vapor Deposition) method.

By performing anisotropic etching on insulating film 5 with a prescribed photoresist (not shown) as a mask, openings exposing surfaces of source/drain regions 4a and 4b are formed and by filling the openings with, for example, a polysilicon film, plugs 6a and 6b are formed therein. Bit liner 7 is formed on insulating film 5. Insulating film 9 is formed so as to cover bit line 7 by means of, for example, a CVD method.

By performing anisotropic etching of insulating film 9 with a prescribed resist (not shown) as a mask, openings exposing surfaces of plugs 6a and 6b are formed. By filling openings with, for example, a polysilicon film, storage node plugs 8 are formed. Silicon oxide film 10 as an insulating film is formed on insulating film 9 by means of, for example, a CVD method.

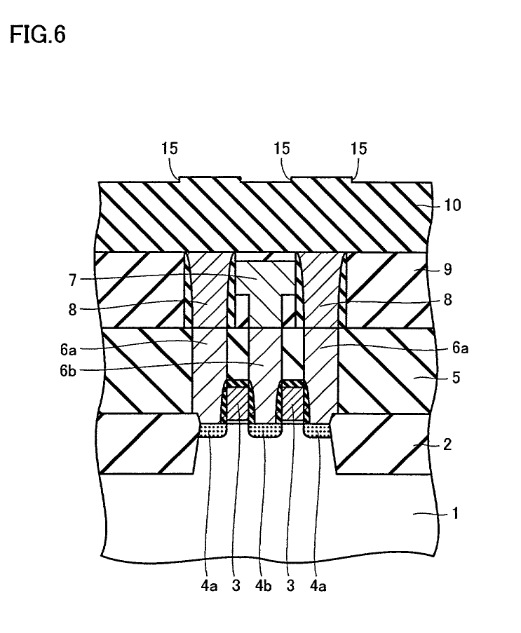

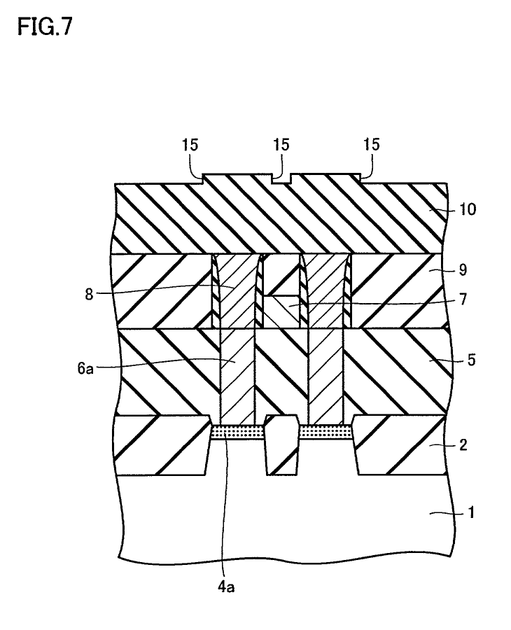

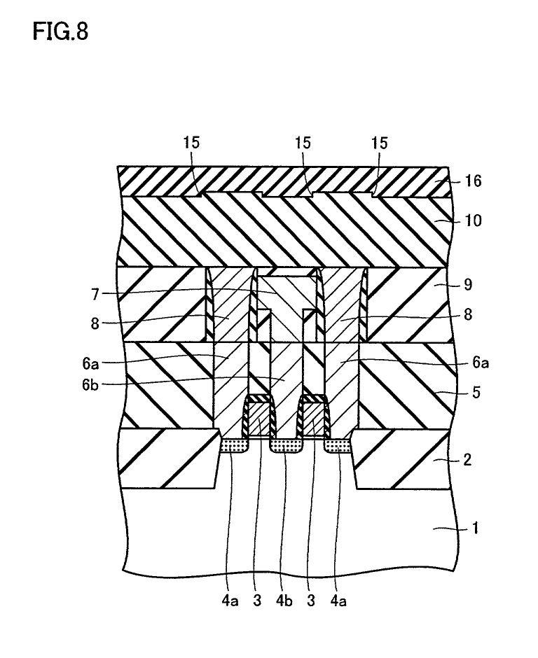

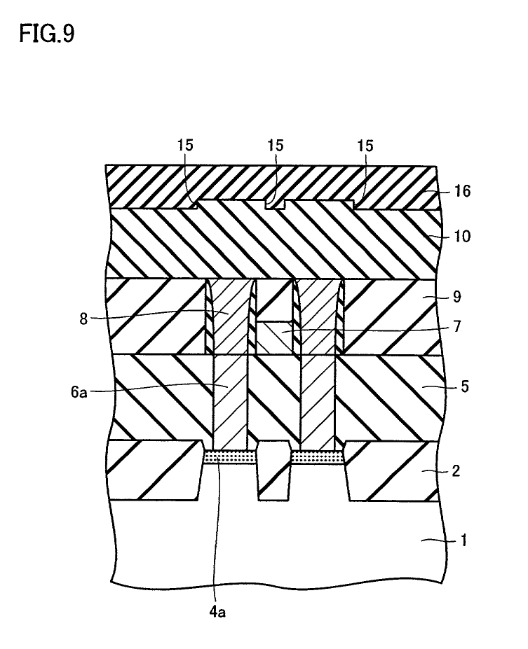

Then, as shown in FIGS. 6 and 7, depressions 15 are formed on the surface of silicon oxide film 10 with a prescribed photoresist (not shown) as a mask. Thereafter, as shown in FIGS. 8 and 9, silicon nitride film 16 having an etching property different from that of silicon oxide film 10 is formed on silicon oxide film 10 so as to fill depressions 15 by means of, for example, a CVD method.

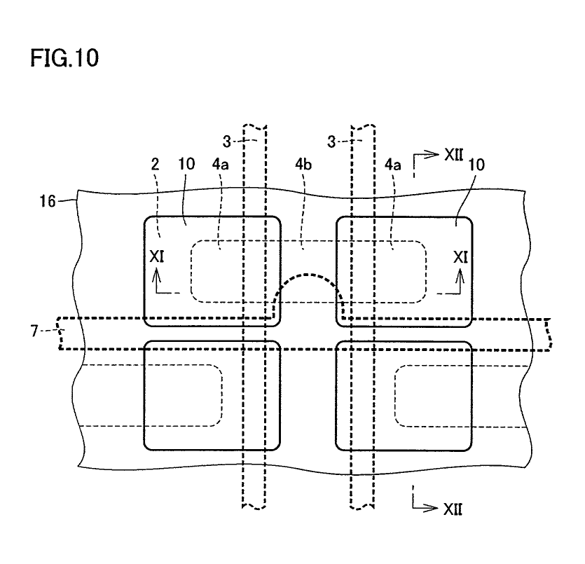

By etching all the surface of silicon nitride film 16, the surface of silicon oxide film 10 in prescribed regions are exposed as shown in FIG. 10 to form silicon nitride film 16 serving as a mask for forming storage node openings.

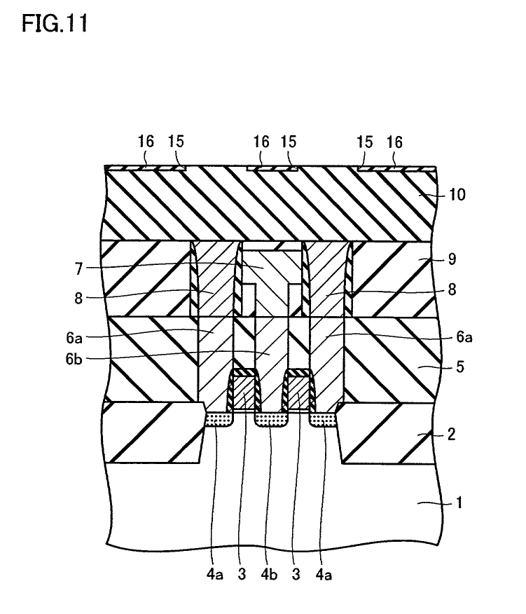

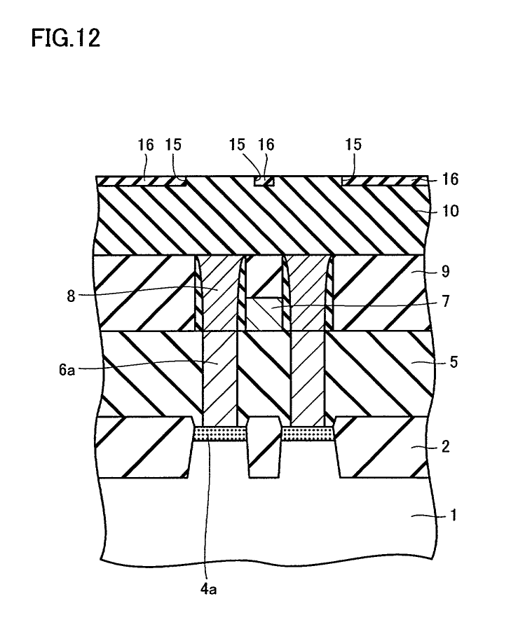

FIG. 11 shows a view of a cross sectional structure in the above step taken on cutting plane line XI-XI shown in FIG. 10 and FIG. 12 shows a view of a cross sectional structure in the above step taken on cutting plane line XII-XII shown in FIG. 10. As shown in FIGS. 11 and 12, depressions 15 is filled with silicon nitride film 16 to thereby cover the surface of silicon oxide film 10 with silicon nitride film 16, except the surface of regions of silicon oxide film 10 in which storage node openings are formed.

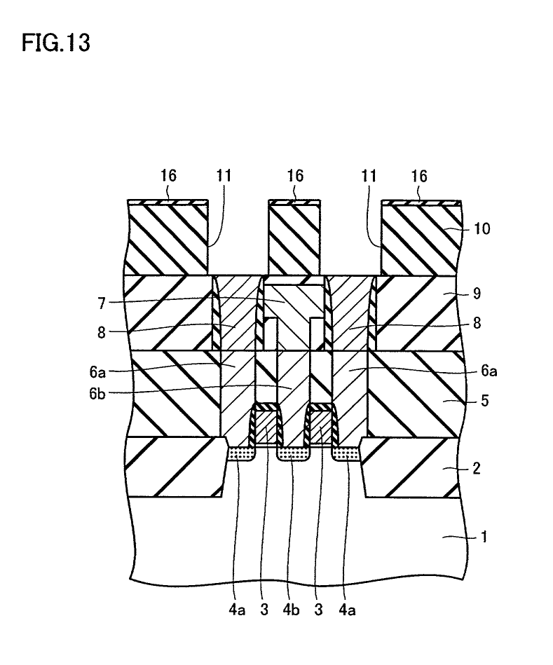

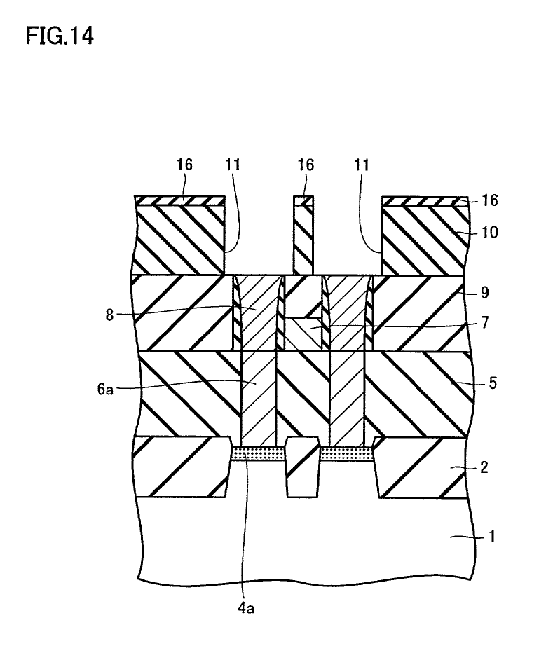

Then, as shown in FIGS. 13 and 14, by applying anisotropic etching to silicon oxide film 10 with silicon nitride film 16 as a mask, storage node openings 11 are formed that exposes surfaces of storage node plugs 8.

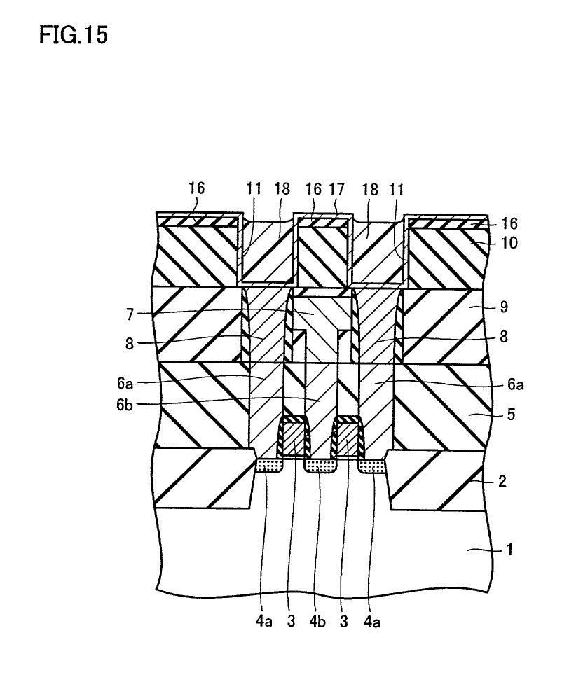

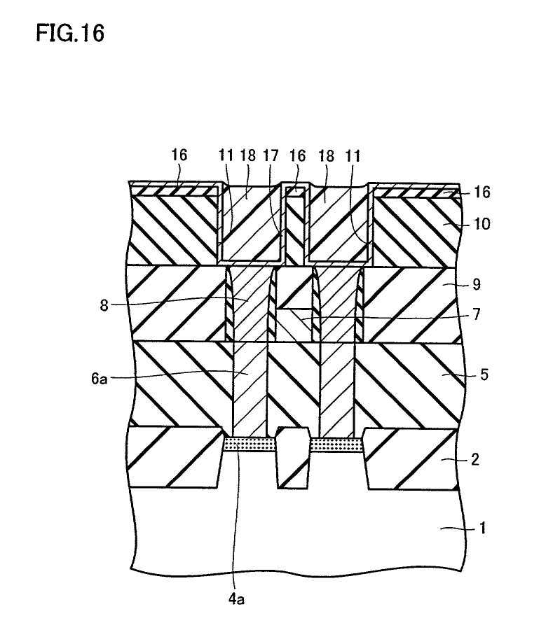

Then, as shown in FIGS. 15 and 16, polysilicon film 17 is formed on the sidewall and bottom surfaces of storage node opening 11 and silicon nitride film 16 by means of, for example, a CVD method. Thereafter, a photoresist 18 is formed only in storage node opening 11. Thereby, polysilicon film 17 in storage node opening 17 is covered by photoresist 18 while exposing a surface of polysilicon film 17 only on silicon nitride film 16.

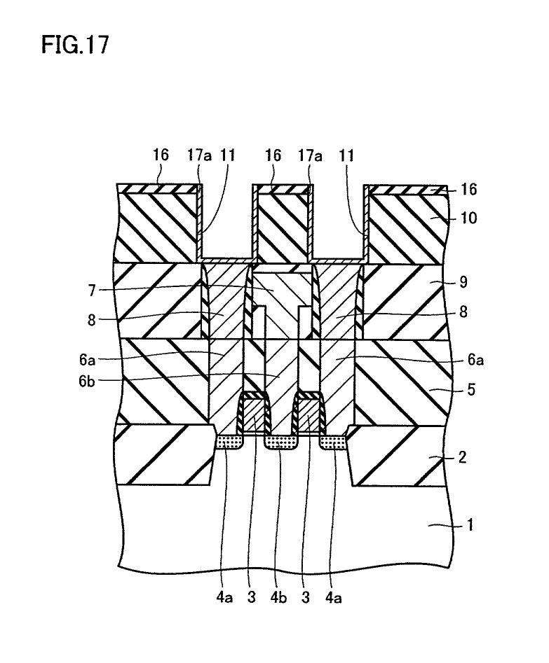

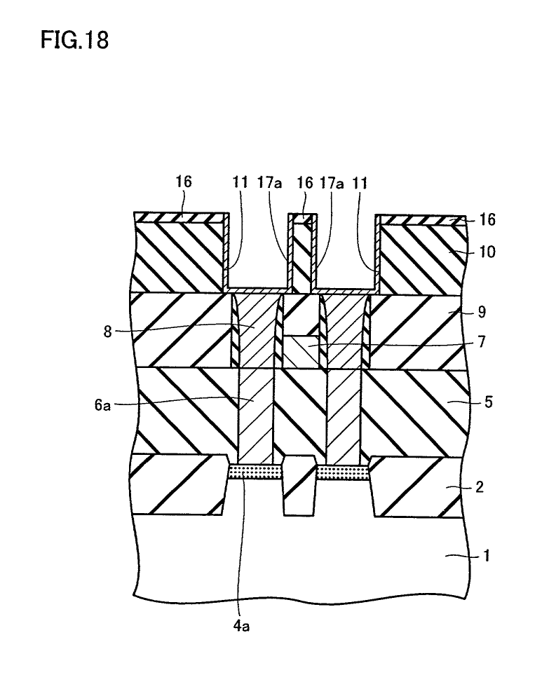

Then, as shown in FIGS. 17 and 18, the exposed surface of polysilicon film 17 is etched off to remove polysilicon film 17 on silicon nitride film 16. Subsequent to this, photoresist 18 in storage node opening 11 is removed. Thereby, storage node 17a is formed in storage node opening 11.

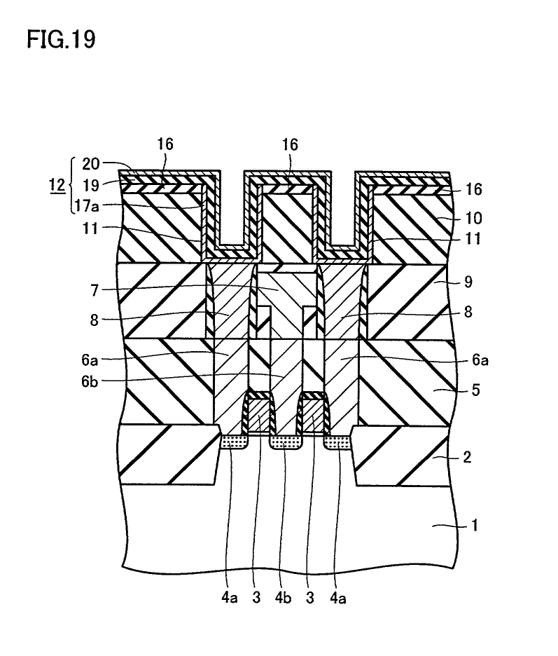

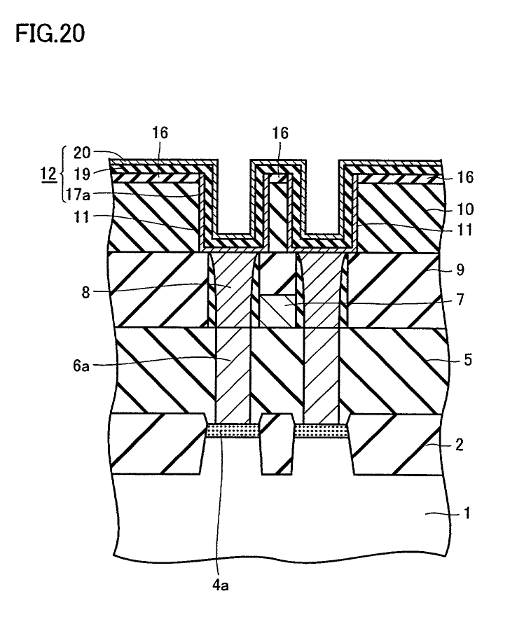

Then, as shown in FIGS. 19 and 20, capacitor dielectric film 19 is formed on storage node 17a by means of, for example, a CVD method. Furthermore, cell plate 20 made of polysilicon film is formed on capacitor dielectric film 19 by means of, for example, a CVD method. In such a way, capacitor 12 is formed that is constituted of storage node 17a, capacitor dielectric film 19 and cell plate 20. Thereafter, interlayer insulating film 13 is formed so as to cover cell plate 20 on semiconductor substrate 1 by means of, for example, a CVD method, thereby completing a main portion of DRAM as shown in FIGS. 2 and 3.

In the manufacturing method of DRAM described above, storage node openings 11 are formed by applying anisotropic etching to silicon oxide film 10 with silicon nitride film 16 having an etching property different from that of silicon oxide film 10 as a mask.

By doing so, as compared with a case where anisotropic etching is applied to silicon oxide film 10 with a photoresist as a mask as performed in a prior art practice, thinning of silicon nitride film 16 as a mask is suppressed, which makes it possible that silicon oxide film 10 can be left with certainty, especially, in regions between adjacent storage node openings 11 each having a narrower spacing, which is shown in FIGS. 1 or 3, after the etching.

As a result, electric short-circuit can be prevented between storage nodes 17a formed subsequent to formation of storage node openings 11, enabling operation of DRAM to be stabilized.

Then, description will be given of an example modification of the manufacturing method of DRAM. In the above method, silicon nitride film 16 serving as a mask material for forming storage node opening 11 is formed in a manner such that silicon nitride film is left only in depressions 15 having been formed in advance on silicon oxide film 10.

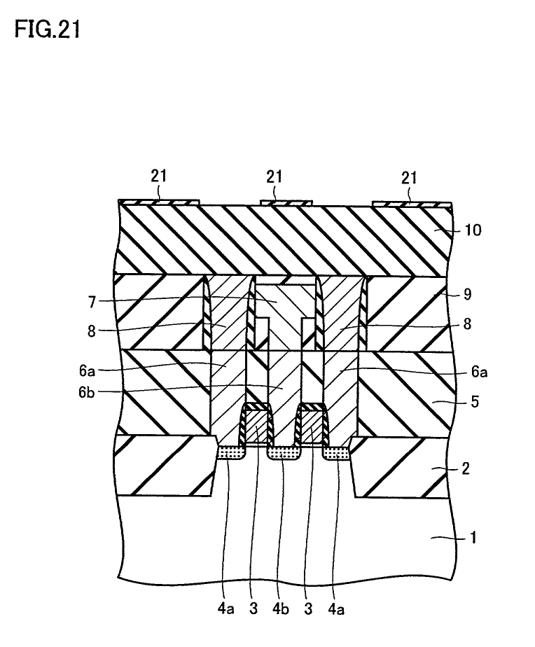

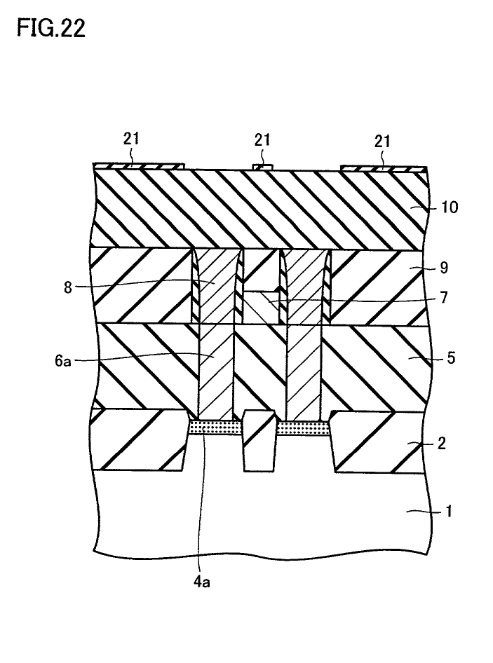

In the manufacturing method relating to this example modification, as shown in FIGS. 21 and 22, a silicon nitride film formed on silicon oxide film 10 is subjected to direct etching with a photoresist (not shown) as a mask without forming depressions on silicon oxide film 10 in advance to thereby form a silicon nitride film 21 as a mask material.

Silicon nitride film 21 as a mask material can also be formed this way and thereafter, silicon oxide film 10 is etched with silicon nitride film 21 as a mask, thereby enabling formation of storage node openings. Note that the other steps associated with this step are substantially the same as those of the above manufacturing method.

Furthermore, description will be given of another example modification of the manufacturing method of DRAM. In the above process, silicon nitride film 16 as a mask material for forming storage node openings 11 is provided on a region (region A) between adjacent storage node openings disposed along a direction along which gate electrode 3 extends and on a region (region B) between adjacent storage openings disposed along a direction along which bit line 7 extends.

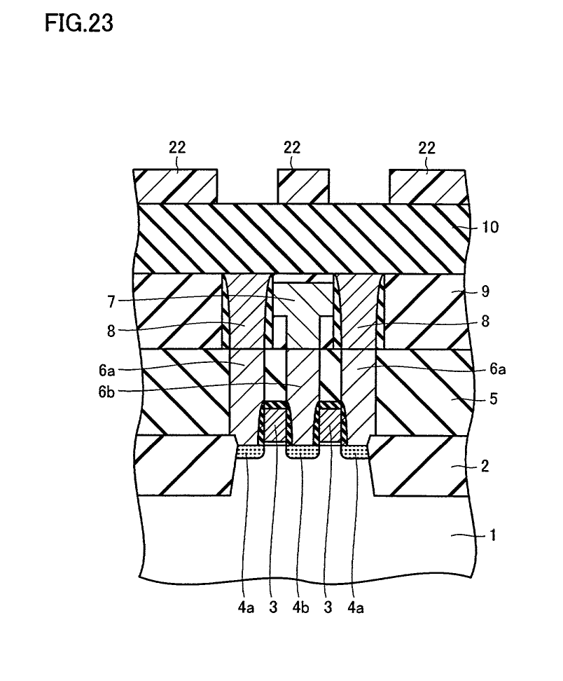

By comparison, a spacing of region B is more than that of region A. Therefore, as shown in FIG. 23, a photoresist 22 may be formed instead of silicon nitride film in regions between adjacent storage node openings disposed along the direction along which bit line 7 extends.

In this case, not only is a pattern of photoresist 22 in the shape of a stripe formed so as to be almost parallel to gate electrode 3, but a pattern of silicon nitride film 16 in the shape of a stripe is formed so as to be almost parallel to bit line 7. Thereafter, silicon oxide film 10 is etched with photoresist 22 and silicon nitride film 16 as masks, thereby enabling storage node openings to be formed.

At this time, since a spacing of region B is broader than that of region A, there is no chance that silicon oxide film 10 on region B is etched off to electrically short-circuit adjacent storage nodes therebetween. Note that the other steps associated with this step are substantially the same as those of the above manufacturing method.

### Third Embodiment

Description will be given of another example of a manufacturing method of DRAM, which relates to a third embodiment of the present invention. In the above manufacturing method of DRAM, description is given of the embodiments, taking up a silicon nitride film as the mask material for forming a storage node opening in silicon oxide film as an example. In description of this embodiment, a polysilicon film is exemplified as a mask material.

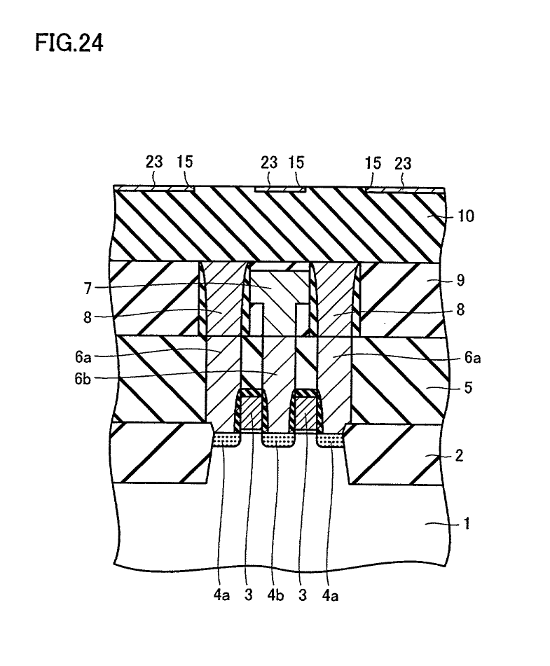

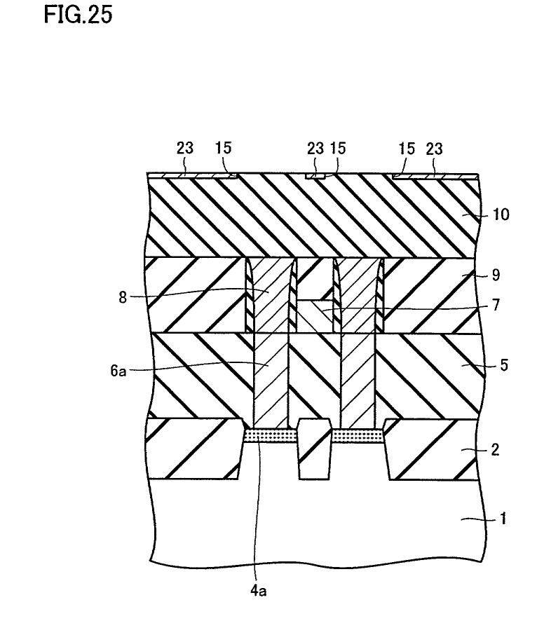

First of all, prescribed depressions 15 are formed in silicon oxide film 10 as shown in FIGS. 24 and 25 after steps similar to those shown in FIGS. 4 to 7 described in the second embodiment. A polysilicon film is formed on silicon oxide film 10 so as to fill depressions 15 by means of, for example, a CVD method, which polysilicon film has an etching property different from that of silicon oxide film 10.

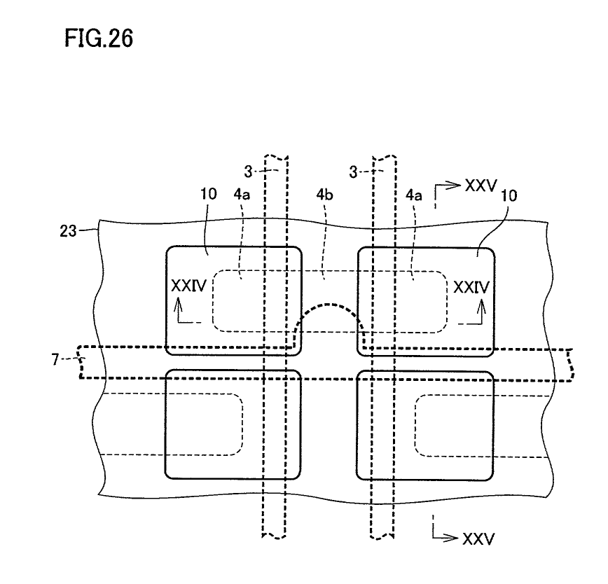

By etching the polysilicon film all over the surface thereof, the surface of silicon oxide film 10 in prescribed regions are, as shown in FIG. 26, exposed while forming polysilicon film 23 serving as a mask material for forming storage node openings. Note that FIGS. 24 and 25 are cross sectional views corresponding to the cutting plane lines XXIV-XXIV and XXV-XXV in FIG. 26.

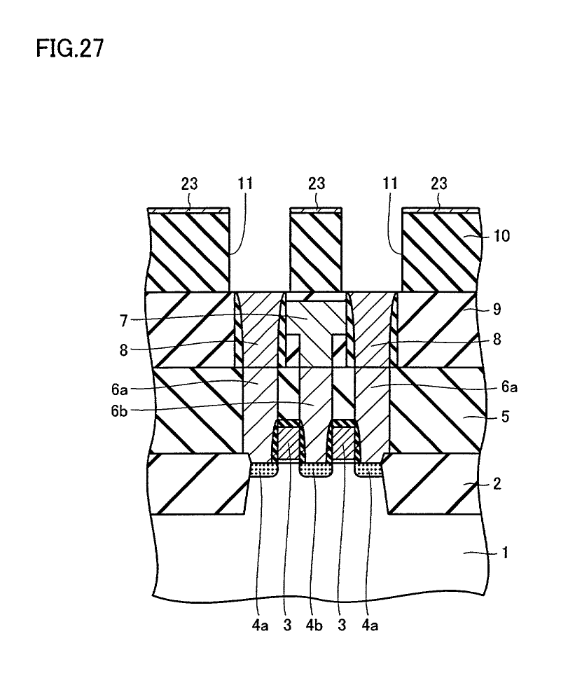

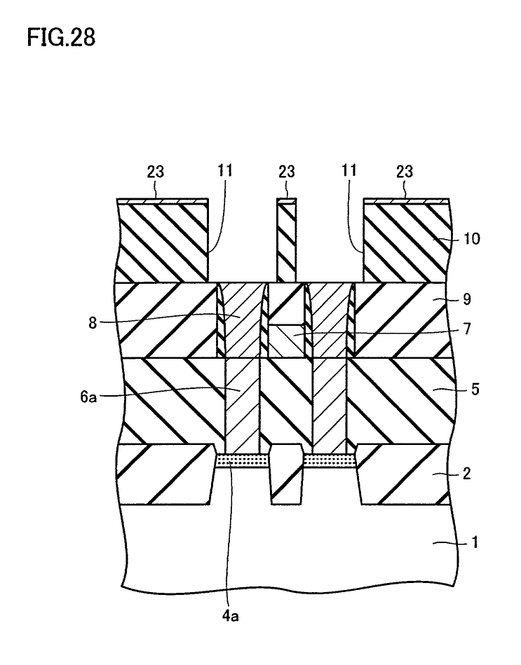

Then, as shown in FIGS. 27 and 28, by applying anisotropic etching to silicon oxide film 10 with polysilicon film 23 as a mask, storage node openings 11 is formed that exposes surfaces of storage node plugs 8. Thereafter, polysilicon film 23 present on silicon oxide film 10 is all removed.

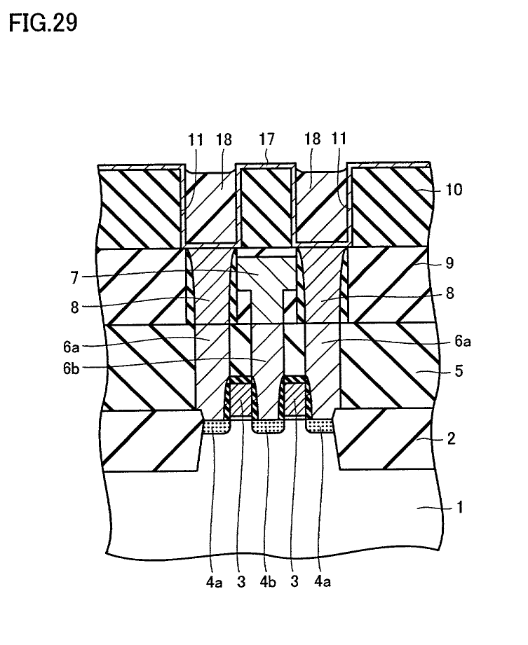

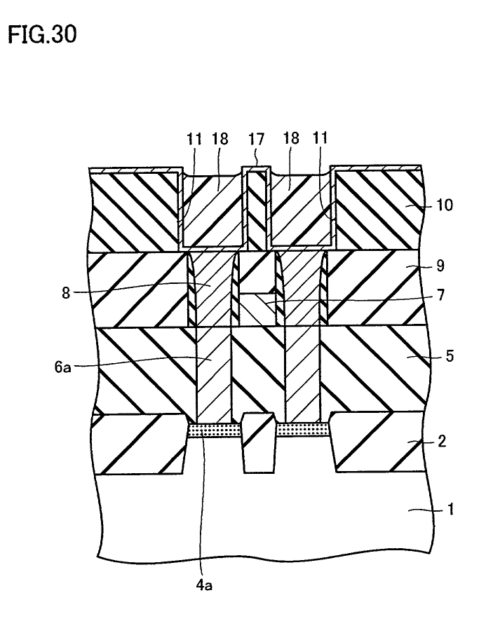

Then, as shown in FIGS. 29 and 30, polysilicon film 17 is formed on the sidewall and bottom surfaces of storage node opening 11 and silicon oxide film 10 by means of, for example, a CVD method. Thereafter, a photoresist 18 is formed only in storage node openings 11. Thereby, polysilicon film 17 in storage node opening 11 is covered by photoresist 18 while exposing the surface of polysilicon film 17 on silicon oxide film 10.

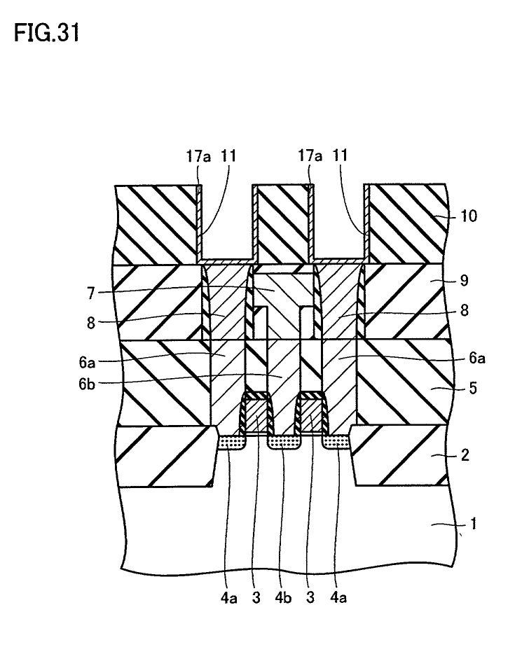

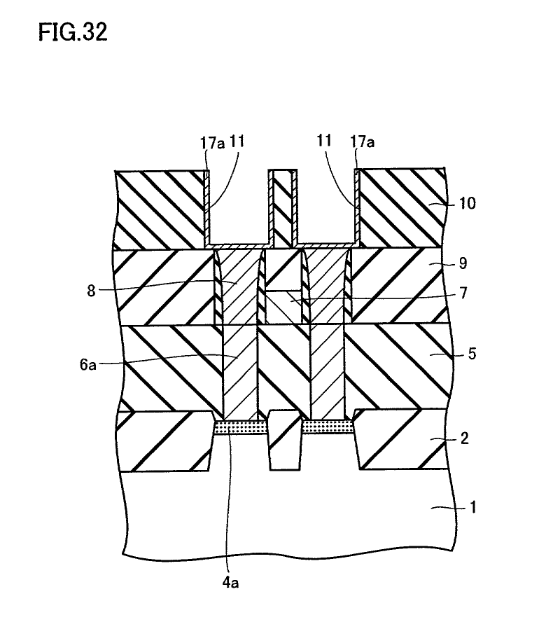

Then, as shown in FIGS. 31 and 32, the surface of exposed polysilicon film 17 is subjected to etching to thereby remove polysilicon film 17 on silicon oxide film 10. Thereafter, photoresist 18 in storage node openings 11 is removed. Thereby, storage nodes 17a are formed in respective storage node openings 11.

Thereafter, a main portion of DRAM is completed by passing through steps similar to those shown in FIGS. 19 and 20 described in the second embodiment.

In the above manufacturing method of DRAM, storage node opening 11 is formed by applying anisotropic etching to silicon oxide film 10 with polysilicon film 23 having an etching property different from that of silicon oxide film 10 as a mask.

As compared with a case where anisotropic etching is applied to silicon oxide film 10 with a photoresist as a mask as performed in a prior art practice, silicon oxide film 10 on regions each having a narrower spacing between adjacent storage node openings shown in FIG. 1 can be left with certainty after the etching since thinning of polysilicon film 23 as a mask is suppressed.

As a result, electric short-circuit can be prevented between storage nodes 17a formed after formation of storage node openings 11, thereby enabling stable operation of DRAM to be ensured.

Note that in this manufacturing method since polysilicon film 23 is applied as a mask material, polysilicon film 23 is required to be removed prior to formation of storage nodes after formation storage node openings 11 in order that no chance arises that adjacent storage nodes are electrically short-circuited therebetween.

In a case where polysilicon film is applied as a mask material, there is a chance that when a mask material is formed by applying a photolithographic technique directly to a polysilicon film, alignment marks are at a time not positioned to a good overlay accuracy in the photolithographic process, with the result that a case occurs where a prescribed mask material of polysilicon film can not be formed with accuracy.

Therefore, by forming depressions on a silicon oxide film in advance as described above and leaving a polysilicon film in the depressions, a mask material of a polysilicon film can be surely formed without applying a photolithographic process to a polysilicon film.

Note that while in the above embodiments, description is given taking up a capacitor as a prescribed element, no specific limitation is directed to a capacitor, as an element formed in an opening, but other elements may be formed there.

The embodiments disclosed above are by way of illustration and example only in all aspects and should not be construed by way of limitation. The present invention is not limited by any of the details of the foregoing description but specified by the claims, and it is intended that the scope of the present invention includes all modifications or alterations in the scope included in not only the terms of the claims but also an additional scope in the sense of equivalency.

What is claimed is:

1. A semiconductor device comprising:
a conductive region formed on a main surface of a semiconductor substrate;
a first insulating film, formed on said semiconductor substrate, and having a prescribed etching property;
openings formed in said first insulating film to expose a surface of said conductive region;
a second insulating film formed on a surface of said first insulating film other than at least sidewall and bottom surfaces of said openings, and having an etching property different from that of said first insulating film; and
prescribed elements including conductive layers formed in said respective openings.

2. The semiconductor device according to claim 1, wherein
said openings are arranged in a matrix with a prescribed spacing between adjacent openings in one direction and a prescribed spacing between adjacent openings in the other direction approximately perpendicular thereto in said first insulating film, and
said second insulating film is formed on said surface of said first insulating film at least in regions thereof between adjacent openings each with a prescribed narrower spacing.

3. The semiconductor device according to claim 1, wherein said second insulating film is formed on a surface of said first insulating film other than said openings.

4. The semiconductor device according to claim 1, comprising
a transistor including a gate electrode and a pair of source/drain regions of a prescribed conductivity type formed on said main surface of said semiconductor substrate; wherein
said conductive region includes one of source/drain regions of said pair; and
each of said prescribed elements includes a capacitor having a storage node, electrically connected to said one of said source/drain regions as said conductive layer, and formed on sidewall and bottom surfaces of a corresponding one of said openings, and a cell plate formed on said storage node with a dielectric film interposing therebetween.

5. The semiconductor device according to claim 1, wherein said first insulating film comprises a silicon oxide film and said second insulating film comprises a silicon nitride film.

6. A manufacturing method of a semiconductor device comprising:
a step of forming a conductive region on a main surface of a semiconductor substrate;
a step of forming an insulating film having a prescribed etching property on said semiconductor substrate;
a step of forming a mask material on said insulating film;
a step of forming openings exposing a surface of said conductive region by etching said insulating film with said mask material as a mask;
a step of forming prescribed elements each including a conductive layer on sidewall and bottom surfaces of a corresponding one of said respective openings, wherein
said step of forming a mask material includes a step of forming a prescribed layer not only different in an etching property from said insulating film but also different from a photoresist.

7. The manufacturing method of a semiconductor device according to claim 6, wherein
in said step of forming a mask material, in order to form said openings arranged in a matrix with a prescribed spacing between adjacent openings in one direction and a prescribed spacing between adjacent openings in the other direction approximately perpendicular thereto in the insulating film, said prescribed layer is formed on a surface of said insulating film other than portions thereof in regions where said openings are formed; and
in a step of forming said openings, said insulating film is etched with said prescribed layer as a mask to thereby form said openings arranged in a matrix.

8. The manufacturing method of a semiconductor device according to claim 6, wherein
in said step of forming a mask material, in order to form said openings arranged in a matrix with a prescribed spacing between adjacent openings in one direction and a prescribed spacing between adjacent openings in the other direction approximately perpendicular thereto in said insulating film, said prescribed layer is formed on a surface of said insulating film in regions each having a prescribed narrower spacing between adjacent openings while a photoresist is formed on said surface of said insulating film in regions each having a prescribed longer spacing between adjacent opening sections; and
in said step of forming said openings, said insulating film is etched with said prescribed layer and said photoresist as masks to thereby form said openings arranged in a matrix.

9. The manufacturing method of a semiconductor device according to claim 6, wherein said step of forming a mask material comprises a step of forming depressions each having a prescribed depth and pattern feature on a surface of said insulating film and a step of forming said prescribed layer only in said depressions.

10. The manufacturing method of a semiconductor device according to claim 6, wherein said step of forming a mask material comprises a step of forming said prescribed layer having prescribed pattern features each of a prescribed depth on a surface of said insulating film.

11. The manufacturing method of a semiconductor device according to claim 6, comprising
a step of forming a transistor including a gate electrode and a pair of source/drain regions of a prescribed conductivity type on said main surface of a semiconductor substrate prior to said step of forming an insulating film, wherein
said step of forming a conductive region includes a step of forming said pair of source/drain regions, and
said step of forming prescribed elements includes a step of forming a storage node on sidewall and bottom surfaces of a corresponding one of said openings as a conductive layer, followed by formation of a cell plate on said storage node with a dielectric film interposing therebetween to form a capacitor.

12. The manufacturing method of a semiconductor device according to claim 6, wherein
in said step of forming an insulating film, a silicon oxide film as said insulating film is formed; and
in said step of forming a mask material, a silicon nitride film as said prescribed layer is formed.

13. The manufacturing method of a semiconductor device according to claim 6, wherein
in said step of forming an insulating film, a silicon oxide film as said insulating film is formed;
in the step of forming a mask material, a polysilicon film as the prescribed layer is formed; and
said method comprising a step of removing said polysilicon film prior to formation of said prescribed elements after said openings are formed.
